(19) United States
(12) Patent Application Publication
(10) Pub. No.: US 2014/0199952 A1
(43) Pub. Date: Jul. 17, 2014

(54) METHOD AND APPARATUS TO REDUCE PA/DEVICE TEMPERATURE BY SWITCHING THE ANTENNAS ON A DEVICE

(71) Applicant: QUALCOMM Incorporated, San Diego, CA (US)

(72) Inventors: Manjinder Singh Sandhu, Poway, CA (US); Madhusudan Kinthada Venkata, San Diego, CA (US); Abhinav Dayal, San Diego, CA (US)

(73) Assignee: QUALCOMM Incorporated, San Diego, CA (US)

(21) Appl. No.: 14/148,175

(22) Filed: Jan. 6, 2014

Related U.S. Application Data
(60) Provisional application No. 61/752,875, filed on Jan. 15, 2013.

(51) Int. Cl. H05K 7/20; H04W 52/18; H04B 1/02

(52) U.S. Cl. CPC H05K 7/20945; H04B 1/02; H04W 52/18
USPC 455/91

(57) ABSTRACT

Methods, systems, and devices are described for thermal management of a wireless communication device. The described techniques may be used, for example, to monitor an operating temperature of the device to determine if the operating temperature has exceeded a threshold value. Other aspects may provide for monitoring of a PA temperature, a transmission power level, and/or input from one or more additional sensors associated with the wireless communication device. Based on any of the above inputs, alone or in combination, an operating temperature of the wireless communication device may be determined When the temperature exceeds the threshold value, a transmission antenna can be switched from a first antenna to a second antenna. Additional aspects may provide for reduction of the transmission power level in response to the operating temperature exceeding the predetermined threshold value.

### CROSS REFERENCES

The present Application for Patent claims priority to U.S. Provisional Patent Application No. 61/752,875 by Sandhu et al., entitled “Method and Apparatus to Reduce PA/Device Temperature by Switching the Antennas on a Device,” filed Jan. 15, 2013, assigned to the assignee hereof, and expressly incorporated by reference herein.

### FIELD OF THE INVENTION

The following relates generally to wireless communication, and more specifically to the reducing the power amplifier (PA) and/or device temperature of a mobile device by switching the antennas on the mobile device.

### BACKGROUND

The following relates generally to wireless communication, and more specifically to the reducing the power amplifier (PA) and/or device temperature by switching the antennas on the device. Wireless communications systems are widely deployed to provide various types of communication content such as voice, video, packet data, messaging, broadcast, and so on. These systems may be multiple-access systems capable of supporting communication with multiple users by sharing the available system resources (e.g., time, frequency, and power). Generally, a wireless multiple-access communications system may include a number of base stations, each simultaneously supporting communication for multiple mobile devices. Base stations may communicate with mobile devices on downstream and upstream links.

Generally, mobile devices generate heat during normal operation. In some circumstances, excessive heat may be generated because of, for example, hardware design and/or layout, high transmission power (which may be related to ambient radio frequency (RF) conditions), or the hand/body position of a user blocking the antenna. Excessive heat associated with the device may lead to a reduction of operational capabilities or premature degradation of the electronic components within the device.

### SUMMARY

The described features generally relate to one or more improved systems, methods, and/or devices for temperature management of a mobile device operating in a wireless communications system. Broadly, the mobile device may include more than one antenna wherein, when an operating temperature associated with the device reaches or exceeds a predetermined threshold value, a transmitting antenna is switched from a first antenna to a second antenna.

In a first set of illustrative examples, provided is a method for thermal management of a wireless communications device having two or more antennas. The wireless communications device may be a user equipment (UE) communicatively coupled with, and operating on, a multicarrier communications system. The method may include monitoring an operating temperature associated with the wireless communication device. The method may also include switching, when the operating temperature exceeds a predetermined threshold value, a transmitting antenna of the wireless communications device from a first antenna to a second antenna. Monitoring the operating temperature may include monitoring a temperature associated with a power amplifier (PA) of the wireless communication device. Monitoring the operating temperature may also include monitoring a temperature identified by a sensor coupled with the PA of the wireless communication device. In some examples, the method may include monitoring a temperature associated with the PA of the wireless communication device and at least one of one or more additional sensors associated with the wireless communication device. The method may provide for determining the second antenna, from a plurality of antennas associated with the wireless communications device, based at least in part on the operating temperature, e.g., when the device includes more than two antennas.

In some aspects, the method may further include monitoring a transmission power level associated with the wireless communication device. The switching determination may be based at least in part on the monitored transmission power level. A transmission power level associated with the wireless communication device may also be monitored, wherein the switching determination is based at least in part on the monitored transmission power level.

In some aspects, the method may include switching the transmitting antenna from the second antenna to the first antenna when the monitored operating temperature of the wireless communications device falls below a second predetermined threshold value. The method may also include switching the transmitting antenna from the second antenna to the first antenna after a predetermined time period has elapsed and the monitored operating temperature of the wireless communications device does not fall or increase in excess of a threshold amount from the pre-switching operating temperature. The switching of the transmitting antenna from the first antenna to the second antenna may be initiated when the operating temperature exceeds the predetermined threshold value for predetermined period of time.

According to a second set of illustrative examples, a wireless communications system configured for thermal management is provided. The system may include means for monitoring an operating temperature associated with the wireless communication device. The system may also include means for switching, when the operating temperature exceeds a predetermined threshold value, a transmitting antenna of the wireless communications device from a first antenna to a second antenna. The wireless communications device may be a UE communicatively coupled with, and operating on, a multicarrier communications system. Monitoring the operating temperature may include means for monitoring a temperature associated with a power amplifier (PA) of the wireless communication device. Monitoring the operating temperature may also include means for monitoring a temperature identified by a sensor coupled with a power amplifier (PA) of the wireless communication device. In some aspects, the monitoring of the operating temperature may even further include means for monitoring a temperature associated with a power amplifier (PA) of the wireless communication device and at least one of one or more additional sensors associated with the wireless communication device. The system may provide for determining the second antenna, from a plurality of antennas associated with the wireless communications device, based at least in part on the operating temperature, e.g., when the device includes at least three antennas.

In some aspects, the system may include means for monitoring a transmission power level associated with the wireless communication device, wherein the switching determination is based at least in part on the monitored transmission power level. Means for reducing the transmission power level of the wireless communications device to a predetermined transmission power level when the operating temperature of the wireless communications device exceeds the predetermined threshold value may also be provided.

Some aspects may provide means for switching the transmitting antenna from the second antenna to the first antenna when the monitored operating temperature of the wireless communications device falls below a second predetermined threshold value. Switching the transmitting antenna from the first antenna to the second antenna may be initiated when the operating temperature exceeds the predetermined threshold value for a predetermined period of time. Further, the system may include means for switching the transmitting antenna from the second antenna to the first antenna after a predetermined time period has elapsed and the monitored operating temperature of the wireless communications device does not fall or increase in excess of a threshold amount from the pre-switching operating temperature.

According to a third set of illustrative examples, a computer program product is provided. The computer program product may be for thermal management of a wireless device. The computer program product may include a non-transitory computer-readable medium having code for monitoring an operating temperature associated with the wireless communication device. The non-transitory computer-readable medium may also include code for switching, when the operating temperature exceeds a predetermined threshold value, a transmitting antenna of the wireless communications device from a first antenna to a second antenna. The wireless communications device may be a UE communicatively coupled with, and operating on, a multicarrier communications system. The code for monitoring the operating temperature may include code for monitoring a temperature associated with a PA of the wireless communication device. The code for monitoring the operating temperature may also include code for monitoring a temperature identified by a sensor coupled with the PA of the wireless communication device. In some aspects, the code for monitoring the operating temperature may further include code for monitoring a temperature associated with a PA of the wireless communication device and at least one of one or more additional sensors associated with the wireless communication device. The non-transitory computer-readable medium may also include code for determining the second antenna, from a plurality of antennas associated with the wireless communications device, based at least in part on the operating temperature.

In some aspects, the non-transitory computer-readable medium may include code for monitoring a transmission power level associated with the wireless communication device, wherein the switching determination is based at least in part on the monitored transmission power level. Code for reducing the transmission power level of the wireless communications device to a predetermined transmission power level when the operating temperature of the wireless communications device exceeds the predetermined threshold value may also be provided.

Even further aspects may include code for switching the transmitting antenna from the second antenna to the first antenna when the monitored operating temperature of the wireless communications device falls below a second predetermined threshold value. Switching the transmitting antenna from the first antenna to the second antenna may be initiated when the operating temperature exceeds the predetermined threshold value for a predetermined period of time. Further, some aspects may include code for switching the transmitting antenna from the second antenna to the first antenna after a predetermined time period has elapsed and the monitored operating temperature of the wireless communications device does not fall or increase in excess of a threshold amount from the pre-switching operating temperature.

According to a fourth set of illustrative examples, a wireless communications device configured for thermal management is provided. The device may include at least one controller. The controller may be configured to monitor an operating temperature associated with the wireless communication device. The controller may also be configured to switch, when the operating temperature exceeds a predetermined threshold value, a transmitting antenna of the wireless communications device from a first antenna to a second antenna. The wireless communications device may be a UE communicatively coupled with, and operating on, a multicarrier communications system. The controller may also be configured to monitor a temperature associated with a power amplifier (PA) of the wireless communication device. The controller may also be configured to monitor a temperature identified by a sensor coupled with a PA of the wireless communication device. In some aspects, the controller may also be configured to monitor a temperature associated with a PA of the wireless communication device and at least one of one or more additional sensors associated with the wireless communication device. The controller may be configured to provide for determining the second antenna, from a plurality of antennas associated with the wireless communications device, based at least in part on the operating temperature.

In some aspects, the controller may be configured to monitor a transmission power level associated with the wireless communication device, wherein the switching determination is based at least in part on the monitored transmission power level. The controller being configured to reduce the transmission power level of the wireless communications device to a predetermined transmission power level when the operating temperature of the wireless communications device exceeds the predetermined threshold value may also be provided.

Some aspects may provide for the controller to be configured to switch the transmitting antenna from the second antenna to the first antenna when the monitored operating temperature of the wireless communications device falls below a second predetermined threshold value. Switching the transmitting antenna from the first antenna to the second antenna may be initiated when the operating temperature exceeds the predetermined threshold value for a predetermined period of time. The controller may also be configured to switch the transmitting antenna from the second antenna to the first antenna after a predetermined time period has elapsed and the monitored operating temperature of the wireless communications device does not fall or increase in excess of a threshold amount from the pre-switching operating temperature.

Further scope of the applicability of the described systems, methods, and/or apparatuses will become apparent from the following detailed description, claims, and drawings. The detailed description and specific examples are given by way of illustration only, since various changes and modifications within the spirit and scope of the description will become apparent to those skilled in the art.

### BRIEF DESCRIPTION OF THE DRAWINGS

A further understanding of the nature and advantages of the present invention may be realized by reference to the following drawings. In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

FIG. 1 shows a block diagram conceptually illustrating an exemplary wireless communications system;

FIG. 2 shows a block diagram conceptually illustrating an exemplary wireless communications device that includes two antennas;

FIG. 3 shows a block diagram conceptually illustrating an exemplary wireless communications device that includes an alternative architecture;

FIG. 4 shows a block diagram conceptually illustrating an exemplary wireless communications device that include yet another alternative architecture;

FIGS. 5A and 5B shows block diagrams conceptually illustrating alternate architectures of portions of an exemplary wireless communications device;

FIG. 6 is a flowchart conceptually illustrating an exemplary method for thermal management of a wireless communications device;

FIG. 7 is a flowchart conceptually illustrating an alternate method for thermal management of a wireless communications device;

FIG. 8 is a flowchart conceptually illustrating an alternative method for thermal management of a wireless communications device; and

FIG. 9 is a flowchart conceptually illustrating another method for thermal management of a wireless communications device.

### DETAILED DESCRIPTION

Thermal management of a wireless communications device is described. An operating temperature (e.g., an operating temperature associated with a power amplifier) of the device may be monitored. When the operating temperature of the device exceeds a predetermined threshold value, a transmission antenna can be switched from a first antenna to a second antenna. The transmission antenna may be switched to the second antenna immediately, or after a predetermined time period has elapsed with the temperature above the predetermined threshold value.

The monitoring may include monitoring a temperature of a power amplifier (PA) of the device, monitoring information from one or more additional sensors associated with the device, and/or monitoring a transmission power level of the device. The transmission antenna may be switched to the second antenna based on the PA temperature, the PA temperature and information from the one or more additional sensors, the PA temperature and the transmission power of the device, or combinations thereof Other aspects may provide for reducing the transmission power when the operating temperature of the device exceeds the predetermined threshold value.

It is to be understood that techniques described herein may be used for various wireless communications systems such as cellular wireless systems, Peer-to-Peer wireless communications, wireless local access networks (WLANs), ad hoc networks, satellite communications systems, and other systems. The terms “system” and “network” are often used interchangeably. These wireless communications systems may employ a variety of radio communication technologies for multiple access in a wireless system such as Code Division Multiple Access (CDMA), Time Division Multiple Access (TDMA), Frequency Division Multiple Access (FDMA), Orthogonal FDMA (OFDMA), Single-Carrier FDMA (SC-FDMA), and/or other technologies. Generally, wireless communications are conducted according to a standardized implementation of one or more radio communication technologies called a Radio Access Technology (RAT). A wireless communications system or network that implements a Radio Access Technology may be called a Radio Access Network (RAN).

Examples of RATs employing CDMA techniques include CDMA2000, Universal Terrestrial Radio Access (UTRA), etc. CDMA2000 covers IS-2000, IS-95, and IS-856 standards. IS-2000 Releases 0 and A are commonly referred to as CDMA2000 1x, 1x, etc. IS-856 (TIA-856) is commonly referred to as CDMA2000 1xEV-DO, High Rate Packet Data (HRPD), etc. UTRA includes Wideband CDMA (WCDMA) and other variants of CDMA. Examples of TDMA systems include various implementations of Global System for Mobile Communications (GSM). Examples of RATs employing FDMA and/or OFDMA include Ultra Mobile Broadband (UMB), Evolved UTRA (E-UTRA), IEEE 802.11 (Wi-Fi), IEEE 802.16 (WiMAX), IEEE 802.20, Flash-OFDM, etc. UTRA and E-UTRA are part of Universal Mobile Telecommunication System (UMTS). 3GPP Long Term Evolution (LTE) and LTE-Advanced (LTE-A) are new releases of UMTS that use E-UTRA. UTRA, E-UTRA, UMTS, LTE, LTE-A, and GSM are described in documents from an organization named “3rd Generation Partnership Project” (3GPP). CDMA2000 and UMB are described in documents from an organization named “3rd Generation Partnership Project 2” (3GPP2). The techniques described herein may be used for the systems and radio technologies mentioned above as well as other systems and radio technologies.

Thus, the following description provides examples, and is not limiting of the scope, applicability, or configuration set forth in the claims. Changes may be made in the function and arrangement of elements discussed without departing from the spirit and scope of the disclosure. Various examples may omit, substitute, or add various procedures or components as appropriate. For instance, the methods described may be performed in an order different from that described, and various steps may be added, omitted, or combined. Also, features described with respect to certain examples may be combined in other examples.

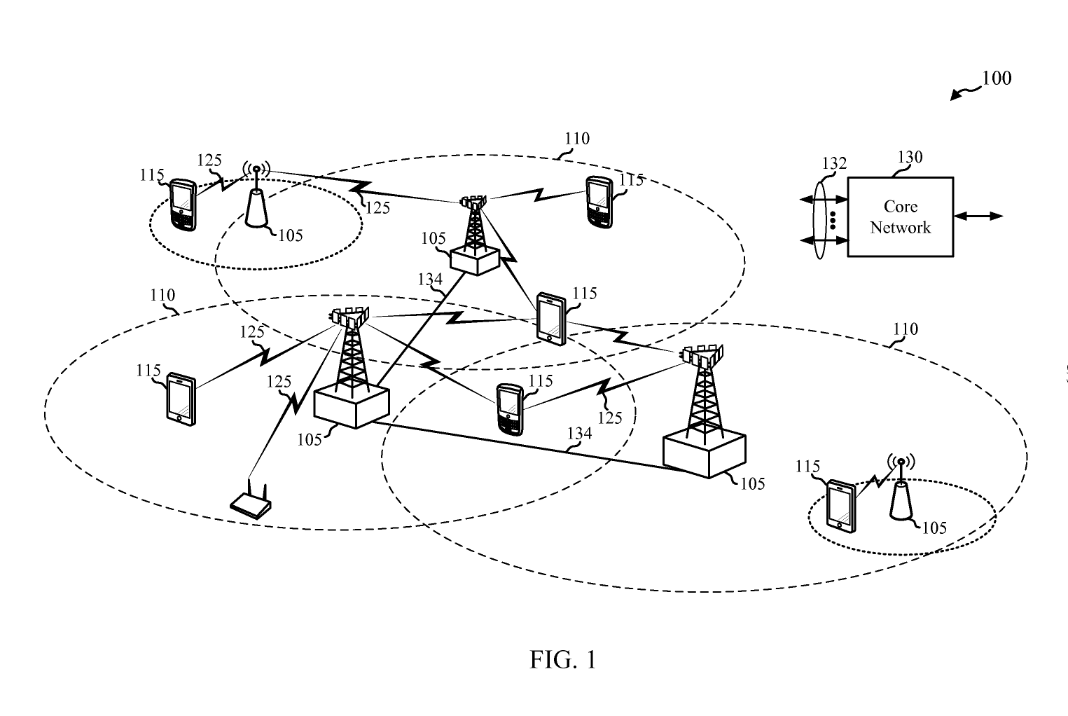

Referring first to FIG. 1, a block diagram conceptually illustrating an exemplary wireless communications system 100. The wireless communications system 100 includes base stations (or cells or nodes) 105, mobile devices 115, and a core network 130. The base stations 105 may communicate with the mobile device 115 under the control of a base station controller (not shown), which may be part of the core network 130 or the base stations 105 in various examples. Base stations 105 may communicate control information and/or user data with the core network 130 through backhaul 132. In certain examples, the base stations 105 may communicate, either directly or indirectly, with each other over backhaul links 134, which may be wired or wireless communication links. The core network 130 may include network entities such as a Serving Gateway, a Packet Data Serving Node, a Packet Data Network Gateway, a Mobility Management Entity, etc.

The wireless communications system 100 may support operation on multiple carriers (waveform signals of different frequencies). Multi-carrier transmitters can transmit modulated signals simultaneously on the multiple carriers. For example, each modulated signal may be a multi-carrier channel modulated according to the various radio technologies described above. Each modulated signal may be sent on a different carrier and may carry control information (e.g., pilot signals, control channels, etc.), overhead information, data, etc. The wireless communications system 100 may include multiple RANs with overlapping or non-overlapping coverage areas.

Mobile devices 115 (e.g., user equipment, etc.) may include smart phones, cellular phones and wireless communications devices, personal digital assistants (PDAs), tablets, other handheld devices, netbooks, ultrabooks, smartbooks, notebook computers, and other type of wireless communications devices. In the ensuing description, various techniques are described as applied to mobile devices 115 operating on a multicarrier communications system (e.g., wireless communications system 100), but principles are applicable to a variety of devices and other systems. The terms “mobile device,” “user equipment,” and “wireless communication device” may be used interchangeably.

The base stations 105 may wirelessly communicate with the mobile devices 115 via one or more base station antennas. The base stations 105 may communicate with the mobile devices 115 under the control of the base station controller via multiple carriers. Each of the base station 105 sites may provide communication coverage for a respective geographic area. In some examples, base stations 105 may be referred to as a base transceiver station, a radio base station, an access point, a radio transceiver, a basic service set (BSS), an extended service set (ESS), a NodeB, eNodeB (eNB), Home NodeB, a Home eNodeB, or some other suitable terminology. The coverage area for each base station 105 here is identified as 110 and is generally shown in dashed line circles. The coverage area for a base station 105 may be divided into sectors (not shown). The wireless communications system 100 may include base stations 105 of different types (e.g., macro, pico, and/or femto base stations). A macro base station may provide communication coverage for a relatively large geographic area (e.g., 35 km in radius). A pico base station may provide coverage for a relatively small geographic area (e.g., 2 km in radius), and a femto base station may provide communication coverage for a relatively smaller geographic area (e.g., 50 m in radius). There may be overlapping coverage areas for different technologies.

The mobile devices 115 may be dispersed throughout the coverage areas 110. Each mobile device 115 may be stationary or mobile. In one configuration, the mobile devices 115 may be able to communicate with different types of base stations such as, but not limited to, macro base stations, pico base stations, and femto base stations, via links 125.

Mobile devices 115 monitor pilot signals from base stations 105 to determine which networks and/or base stations 105 may provide the best downlink and/or uplink channel conditions. The mobile devices 115 may then select a RAN and/or particular base station 105 for communication and register or “camp” on the network. Registration of a mobile device 115 on a network may also be called network attachment. Registration and/or attachment may include sending an attach request from the device to the RAN, allocating a device identifier for the registered device (e.g., Temporary Mobile Subscriber Identity (TMSI), and the like), authentication of the mobile device 115 on the network, bearer context setup in the mobile device 115 and network, and/or mobility management by the network.

Generally, mobile devices 115 update network registration periodically and/or when a the mobile device 115 detects a change to a parameter that may affect bearer context setup with the network. For example, existing mobile devices 115 may perform explicit registration when they are turned ON and OFF, if frequency band or class changes, periodically after a specific time duration, periodically after traveling a specified distance, upon entering a new zone (e.g., network location area, etc.) of the network, and/or based on a change in various device parameters.

Certain aspects provide for an operating temperature of a mobile device 115 to be monitored. The operating temperature may be monitored by receiving information from one or more sensors associated with the mobile device 115. The mobile device 115 may include a power amplifier (PA) where the operating temperature can be determined by monitoring a temperature of the PA. A sensor may be coupled with, or otherwise be in thermal communication with, the PA of the mobile device 115. The mobile device 115 may include one or more additional sensors. Examples of the one or more additional sensors may include, but are not limited to, temperature sensors positioned within the mobile device 115 and/or temperature sensors positioned on or near a surface of the mobile device 115. Information from the one or more additional sensors may include information indicative of an operating temperature of the mobile device 115. Information from the one or more additional sensors may include information indicative of an operational state of the device (e.g., that the mobile device 115 is transmitting, that the mobile device 115 is in an awake mode or a sleep mode, etc.). Based at least in part on the information from the sensors, an operating temperature of the mobile device 115 may be determined. Additional aspects may provide for a transmission power level associated with the mobile device 115 to be monitored. The transmission power level may be reduced when the operating temperature of the mobile device 115 reaches, or exceeds the predetermined threshold value.

An operating temperature associated with the mobile device 115 may be determined based, at least in part, on (1) the PA temperature of the mobile device 115, (2) information from the one or more additional sensors associated with the mobile device 115, (3) the transmission power level of the mobile device 115, (4) or any combination of the above. In one aspect, the operating temperature of the mobile device 115 may be determined based on (1) the PA temperature of the mobile device 115, (2) the PA temperature of the mobile device 115 in conjunction with information from the one or more additional sensors associated with the mobile device 115, (3) the PA temperature of the mobile device 115 in conjunction with the transmission power level of the mobile device 115, and/or (4) the PA temperature of the mobile device 115 in conjunction with information from the one or more additional sensors and the transmission power level of the mobile device 115.

When the operating temperature of the mobile device 115 exceeds a predetermined threshold value, a transmitting antenna may be switched from a first antenna to a second antenna. Other aspects may provide for determining the second antenna, in mobile devices 115 having more than two antennas, based on the gain of the antenna, the physical location of the antenna on or within the mobile device 115, other operational states of the mobile device 115, etc. The transmission antenna may be switched from the first antenna to the second antenna when the operating temperature exceeds the predetermined threshold value, i.e., immediately. Alternatively, the transmission antenna may be switched from the first antenna to the second antenna after a predetermined time period has elapsed during which the operating temperature exceeds the predetermined threshold value.

Further, in some aspects, the transmitting antenna may be switched from the second antenna back to the first antenna, or a third antenna in mobile devices 115 having more than two antennas, after a predetermined time period and/or if the operating temperature of the device does not fall or increase in excess of a second predetermined threshold amount from the pre-switching operating temperature.

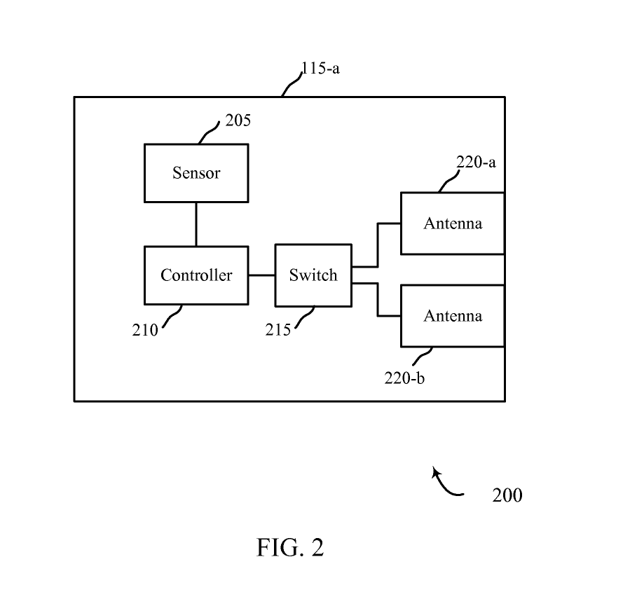

Referring to FIG. 2, a block diagram illustrates an example of a system 200 implementing aspects of the present disclosure. The system 200 includes a mobile device 115-a configured for thermal management. The mobile device 115-a may be an example of one or more aspects of the mobile devices 115, as shown in FIG. 1. In one example, the mobile device 115-a may be configured to implement aspects of the mobile device 115 discussed above with respect to FIG. 1, which may not be repeated here for the sake of brevity. The mobile device 115-a may include a sensor 205, a controller 210, a switch 215, a first antenna 220-a, and a second antenna 220-b. The mobile device 115-a may have an internal power supply (not shown), such as a small battery, to facilitate mobile operation. Each of these components may be in communication with each other, either directly or indirectly. In some cases, these components may be integrated with each other; for example, the sensor 205, controller 210, and/or switch 215 may be integrated.

The components of the mobile device 115-a may, individually or collectively, be implemented with one or more application-specific integrated circuits (ASICs) adapted to perform some or all of the applicable functions in hardware. Alternatively, the functions may be performed by one or more other processing units (or cores), on one or more integrated circuits. In other examples, other types of integrated circuits may be used (e.g., Structured/Platform ASICs, Field Programmable Gate Arrays (FPGAs), and other Semi-Custom ICs), which may be programmed in any manner known in the art. The functions of each unit may also be implemented, in whole or in part, with instructions embodied in a memory, formatted to be executed by one or more general or application-specific processors. Each of the illustrated components may be a means for performing one or more functions related to operation of the mobile device 115-a.

In one aspect, the sensor 205 is configured to provide information indicative of the temperature of the mobile device 115-a to the controller 210. The sensor 205 may be positioned within the mobile device 115-a and configured to be in thermal communication with one or more components of the mobile device 115-a, such as one or more PA(s), wireless modem(s), processor(s) or processing core(s), memory, or antenna(s). As such, the sensor 205 may provide information indicative of the temperature of the mobile device 115-a. In certain examples, the sensor 205 may include a thermistor, a thermocouple, a resistance temperature detector, an infrared sensor, or other sensor providing an analog or digital output reflective of the sensed temperature.

The controller 210 may include logic, code, etc., configured to receive the information from the sensor 205 and determine the operating temperature of the mobile device 115-a based on the received information. The controller 210 may be further configured to determine whether the operating temperature has exceeded a predetermined threshold value. In response to exceeding the predetermined threshold value, the controller 210 may switch a transmitting antenna from the first antenna 220-a to the second antenna 220-b. The controller 210 may be in operative communication with the switch 215 and provide instructions causing the switch 215 to redirect a transmission signal from the first antenna 220-a to the second antenna 220-b.

In some aspects, the predetermined threshold value may be determined based on one or more parameters associated with the mobile device 115-a. For example, one or more components of the mobile device 115-a may have an associated safe operating temperature range where the components will not result in an unacceptable reduction of operational capabilities or premature degradation. In other aspects, the predetermined threshold value may also, or alternatively be based on a temperature a user of the mobile device 115-a may consider too warm. For instance, the mobile device 115-a may be configured to implement the disclosed temperature management techniques to keep the mobile device 115-a from being too warm to the touch of the user.

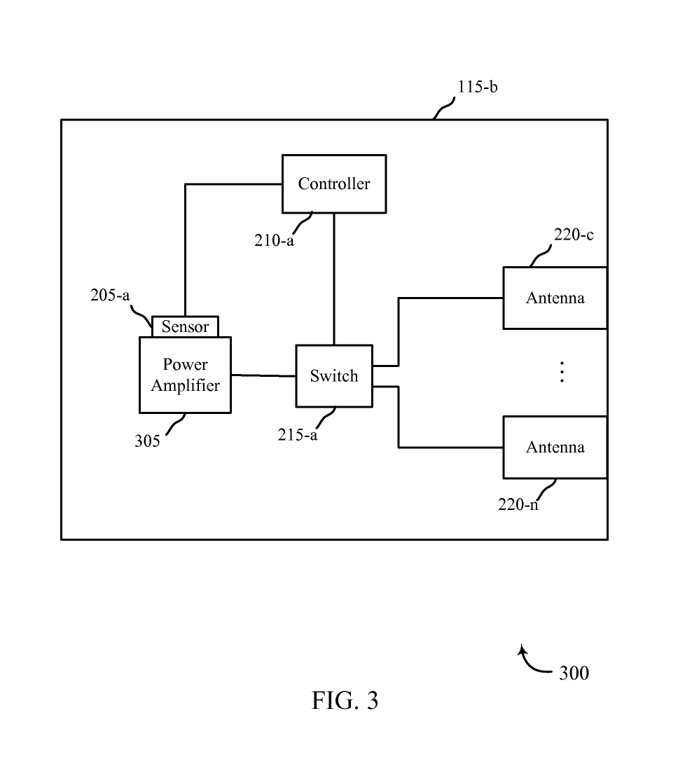

Turning next to FIG. 3, a block diagram conceptually illustrating a system 300 implementing aspects of the present disclosure. The system 300 may include a mobile device 115-b. The mobile device 115-b may be an example of one of the mobile devices 115 shown in FIG. 1 or 2. In one example, the mobile device 115-b may be configured to implement aspects of the mobile devices 115 discussed above with respect to FIGS. 1 and 2, which may not be repeated here for the sake of brevity. The mobile device 115-b includes a sensor 205-a, a controller 210-a, a switch 215-a, a number of antennas 220 (identified by reference numerals 220-c to 220-n), and a power amplifier 305. The mobile device 115-b may have an internal power supply (not shown), such as a small battery, to facilitate mobile operation. Similar to the mobile device 115-a described above with respect to FIG. 1, each of these components may be in communication with each other and/or may be integrated. Similarly, the controller 210-a may be a processor. When the controller 210-a is a processor, other components may be integrated into the processor, e.g., the sensor 205-a and/or the switch 215-a. Each component may be a means for performing one or more functions related to operation of the mobile device 115-b.

Generally, in the example illustrated in FIG. 3, the operating temperature of the mobile device 115-b may be based on a PA temperature of the PA 305. For instance, the sensor 205-a may be in thermal communication with the PA 305, in direct contact with the PA 305 (e.g., attached, coupled with, etc.), or otherwise be associated with the PA 305 to provide information indicative of a PA temperature associated with PA 305. The PA temperature may be used to determine, or simply may be considered, the operating temperature of the mobile device 115-b.

The controller 210-a may include logic, code, or otherwise be configured to receive information from the sensor 205-a and use the information to determine the PA temperature of the PA 305. The controller 210-a may further be configured to switch a transmission antenna from a first antenna to a second antenna. As illustrated in FIG. 3, the mobile device 115-b includes two or more antennas, the antennas being identified by reference numerals 220-c to 220-n, where n would be determined based on the number of antennas of the mobile device 115-b. The switch 215-a may be include hardware, logic, or be otherwise configured to direct a transmission signal from the PA 305 to any of the plurality of antennas 220 to be transmitted on the wireless communications system 100.

The controller 210-a may be configured to determine, based on information received from the sensor 205-a, whether the PA temperature has exceeded a predetermined threshold and, in response, communicate with the switch 215-a to direct the switch 215-a to switch the transmission signal from the transmission antenna (e.g., the first antenna 220-c) to a second antenna (e.g., the second antenna 220-n).

The controller 210-a may further be configured to determine which of the plurality of antennas 220 to switch the transmission antenna to. As an example, the controller 210-a may determine which antenna 220 to switch the transmission antenna to based on the location of each of the antennas 220, the particulars specification or parameters of each of the antennas 220 (e.g., antenna gain, configuration, etc.), or other factors. In the instance where the PA temperature has risen because of poor transmission characteristics, e.g., because the transmission antenna is blocked, the controller 210-a may be configured to determine a second antenna to switch the transmission signal to based on the second antenna being located on a different part of the mobile device 115-b.

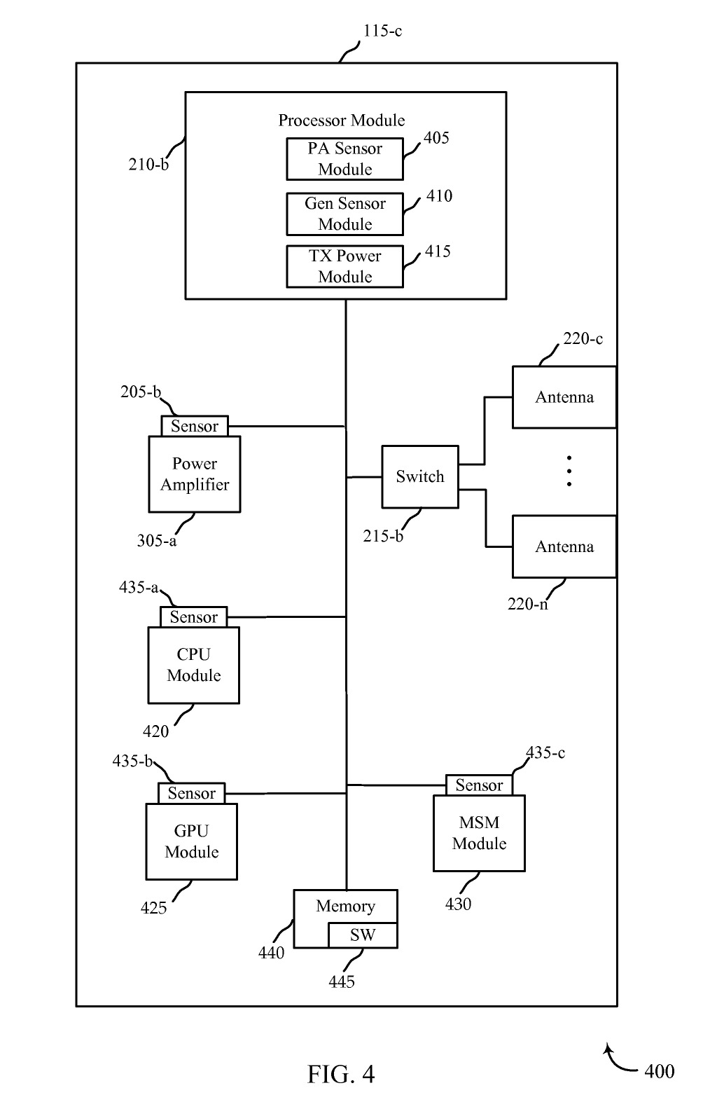

Turning to FIG. 4 now, a block diagram conceptually illustrating an example system 400 configured to implement aspects of the disclosure. The system 400 may include a mobile device 115-c that is configured for thermal management. The mobile device 115-c may be an example of one or more of the mobile devices 115 of FIG. 1, 2, or 3. That is, in some aspects, the mobile device 115-c may be configured to implement aspects of the mobile devices 115 discussed above, which may not be repeated here for the sake of brevity. The mobile device 115-c includes a processor module 210-b (which may be an example of controller 210 of FIG. 2 or 3), a switch 215-b, a plurality of antennas 220 (being illustrated as antennas 220-c to 220-n), and a sensor 205-b associated with PA 305-a. The processor module 210-b includes a PA sensor module 405, a general sensor module 410, and a transmission (TX) power module 415. The mobile device 115-c additionally includes a central processor unit (CPU) module 420, a graphics processor (GPU) module 425, a mobile station modem (MSM) module 430, and a memory 440 including computer-executable software code 445. The mobile device 115-c also includes one or more, or a plurality of additional sensors 435 associated with one or more components of the mobile device 115-c. In the example illustrated in FIG. 4, the CPU module 420 has an associated sensor 435-a, the GPU module 425 has an associated sensor 435-b, and the MSM module 430 has an associated sensor 435-c. The mobile device 115-c may have an internal power supply (not shown), such as a battery, to facilitate mobile operations.

Each of the components of the mobile device 115-c may be in communication, directly or indirectly, with each other (e.g., via bus). Furthermore, these components may be integrated. As an example, the processor module 210-b, the CPU module 420, the GPU module 425, the memory 440, and/or the switch 215-b may be integrated. The mobile device 115-c may have any of various configurations and be coupled with a radio access network and/or one or more other mobile devices 115, 115-a, 115-b, for example.

The components of the mobile device 115-c may, individually or collectively, be implemented with one or more application-specific integrated circuits (ASICs) adapted to perform some or all of the applicable functions in hardware. Alternatively, the functions may be performed by one or more other processing units (or cores), on one or more integrated circuits. In other examples, other types of integrated circuits may be used (e.g., Structured/Platform ASICs, Field Programmable Gate Arrays (FPGAs), and other Semi-Custom ICs), which may be programmed in any manner known in the art. The functions of each unit may also be implemented, in whole or in part, with instructions embodied in a memory, formatted to be executed by one or more general or application-specific processors.

Each of the components may be a means for performing one or more functions related to operation of the mobile device 115-c.

The memory 440 may include random access memory (RAM) and read-only memory (ROM). The memory 440 may store computer-readable, computer-executable software code 445 containing instructions that are configured to, when executed, cause the processor module 210-b to perform various functions described herein (e.g., thermal management of the mobile devices 115-c). Alternatively, the computer-executable software code 445 may not be directly executable by the processor module 210-b but be configured to cause the CPU module 420 (e.g., when compiled and executed) to perform functions described herein.

The PA sensor module 405, the general sensor module 410, and the TX power module 415 may be implemented as computer executable instructions that, when executed by the processor module 210-b, implement aspects of the functions described herein. In one example, one or more of the modules 405, 410, 415 may be implemented as code running on the processor module 210-b and receiving information from the respective sensors 205-b, 435-a, 435-b, and 435-c. The modules 405, 410, 415 may, upon receipt of the information, include instructions to determine, for example, the operating temperature of the mobile device 115-c.

The one or more additional sensors 435 may be configured to provide information related to their associated module, e.g., information indicative of a physical characteristic of the associated module, information of the status or operational state of the associated module, information of the electrical characteristics of the module, etc. The sensors 205-b, 435-a, 435-b, and 435-c may provide the information to the processor module 210-b. The processor module 210-b may include logic, code, instructions, etc., for, based on information received from one or more of the sensors, performing thermal management of the mobile device 115-c.

The mobile device 115-c may be configured to implement aspects discussed above for facilitating thermal management of the mobile device 115-c. Certain aspects may provide for a PA temperature of the mobile device 115-c to be monitored. The PA temperature may be monitored by having the processor module 210-b receive information from the sensor 205-b associated with the PA 305-a. The PA sensor module 405 may process the information and make decisions related to PA temperature and related switching. The sensor 205-b may be coupled with, or otherwise be in thermal communications with the PA 305-a. The mobile device 115-c includes one or more additional sensors 435 and permits additional information to be utilized to determine whether the transmission antenna needs to be switched from the first antenna to a second antenna. That is, information from the one or more additional sensors 435 may include information indicative of an operating temperature of the mobile device 115-c. These temperatures may be monitored by having the general sensor module 410 receive information from the sensors 435 associated with various components.

The general sensor module 410 may process the information from the sensor(s) 205-b and/or 435 and make decisions related to device temperature and related switching. Information from the one or more additional sensors 435 may include information indicative of an operational state of the mobile device 115-c (e.g., that the device is transmitting, that the device is in an awake mode or a sleep mode, etc.) wherein, based at least in part on the information, an operating temperature of the mobile device 115-c may be determined Additional aspects may provide for a transmission power level associated with the mobile device 115-c to be monitored. The transmission power level may be monitored via the processor module 210-b receiving information from, for example, the CPU module 420 and/or the PA 305-a indicative of the transmission power the PA 305-a is transmitting at. The transmission power may be monitored by having the Tx power module 415 receive information. The Tx power module 415 may process the information and make decisions related to transmit power and related switching. The transmission power level may be reduced when the operating temperature of the mobile device 115-c exceeds the predetermined threshold value.

As shown in the architecture of the mobile device 115-c of FIG. 4, the predetermined threshold temperature of the mobile device 115-c may be determined based on a range of data. For example, the temperature may be based, at least in part, on (1) the PA temperature of the mobile device 115-c, (2) information from the one or more additional sensors 435, (3) the transmission power level of the mobile device 115-c, (4) or any combination of the above. In another aspect, the operating temperature of the mobile device 115-c may be determined based on (1) the PA temperature of the mobile device 115-c, (2) the PA temperature of the mobile device 115-c in conjunction with information from the one or more additional sensors 435, (3) the PA temperature of the mobile device 115-c in conjunction with the transmission power level of the mobile device 115-c, and/or (4) the PA temperature of the mobile device 115-c in conjunction with information from the one or more additional sensors 435 and the transmission power level of the mobile device 115-c.

When an operating temperature of the mobile device 115-c exceeds a predetermined threshold value, a transmitting antenna may be switched from a first antenna (e.g., antenna 220-c) to a second antenna (e.g., antenna 220-n). Other aspects may provide for determining the second antenna based on the gain of the antenna, the physical location of the antenna on or within the mobile device 115-c, other operational states of the mobile device 115-c, etc. The transmission antenna may be switched from the first antenna to the second antenna when the operating temperature exceeds the predetermined threshold value, i.e., immediately. Alternatively, the transmission antenna may be switched from the first antenna to the second antenna after a predetermined time period has elapsed when the operating temperature exceeds the predetermined threshold value. The transmission antenna may be switched from the first antenna to the second antenna after a predetermined time period has elapsed and the operating temperature of the mobile device 115-c does not fall or increase in excess of a threshold amount from the pre-switching operating temperature. Further, the transmitting antenna may be switched from the second antenna back to the first antenna, or a third antenna, after a predetermined time period and/or if the operating temperature of the mobile device 115-c does not fall or increase in excess of a threshold amount from the pre-switching operating temperature.

It is to be understood that the processor module 210-b may include a variety of logical algorithms to determine an operating temperature of the mobile device 115-c, based on the configuration of the mobile device 115-c (e.g., depending on how many, and what type of additional sensors 435 are included in the mobile device 115-c). Any number of algorithms, computer executable instructions, code, etc., schemes can be implemented by the processor module 210-b to determine the operating temperature of the mobile device 115-c. As one example, a high PA temperature may indicate that the mobile device 115-c has exceeded the predetermined threshold value, and thus the transmission antenna should be switched. In another example, a low PA temperature reading in conjunction with a high temperature reading from the additional sensor 435-b (the GPU module 425 sensor), might indicate that, although the mobile device 115-c is hot, the transmission antenna may not need to be switched, i.e., the transmission antenna may not be the reason for the high operating temperature. As yet another example, a high PA temperature reading coupled with a high transmission power level may indicate to the processor module 210-b that the excessive heat may be caused by transmission power level, rather than the particular transmission antenna. As such, the processor module 210-b may communicate to the CPU module 420 that the transmission power level should be reduced to mitigate the excessive heat.

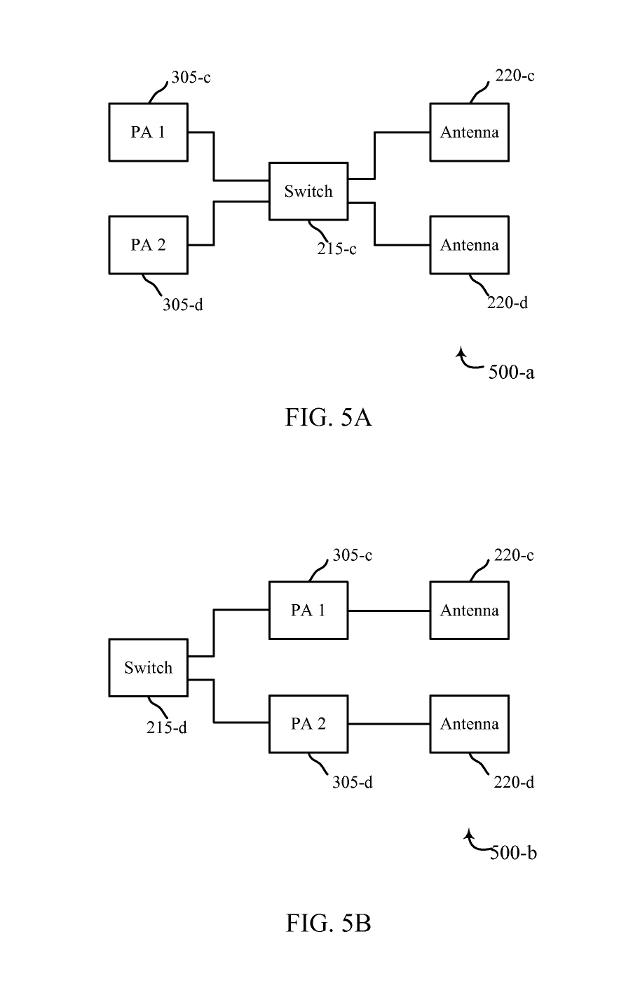

Turning to FIGS. 5A and 5B now, a block diagram conceptually illustrating alternate architectures 500-a and 500-b illustrating portions of the mobile devices 115 of FIGS. 1-4. The architecture 500-a of FIG. 5A includes a PA 1 305-c, a PA 2 305-d, a switch 215-c, a first antenna 220-c, and a second antenna 220-d. Similarly, the architecture 500-b of FIG. 5B includes a switch 215-d, PAs 305-c and d, and first and second antennas 220c and d, respectively. As before, these components may be in communication with each other and also may be integrated.

Temperature based antenna switching can also be employed for transmitter architectures (e.g., the architectures 500-a and 500-b of FIGS. 5A and 5B, respectively) where the antennas are being fed by independent power controlled PAs, (e.g., PA1 305-c and PA 2 305-d). It may be understood that antenna switching may not provide current consumption benefit in such systems since the overall device transmit power is the same. It can, however, be used to distribute the high temperature points over the area of the mobile devices 115, i.e., it can be used for zone based thermal mitigation.

For example, in uplink multiple-input multiple output (MIMO) systems with independent power control for the two PAs individual PA temperatures can be used to switch the antenna for the transmitter paths. If the temperature of one PA is higher than the threshold and it is found that the other PA is transmitting at a lower power, one can switch the antennas, so the that the other PA now takes higher load and the heat source can be distributed in space or moved to another zone. The temperature gap for switching antennas can be controlled to prevent frequent switches, i.e., temperature hysteresis can be used.

With more particular reference to the architecture 500-b of FIG. 5B, where multiple PAs may be available for the same band, a switch can be used before the power amplifier or the transmitter paths itself can be switched so that the high heat source is relocated. In this case, both PAs may be sharing a single antenna or different antennas may be used.

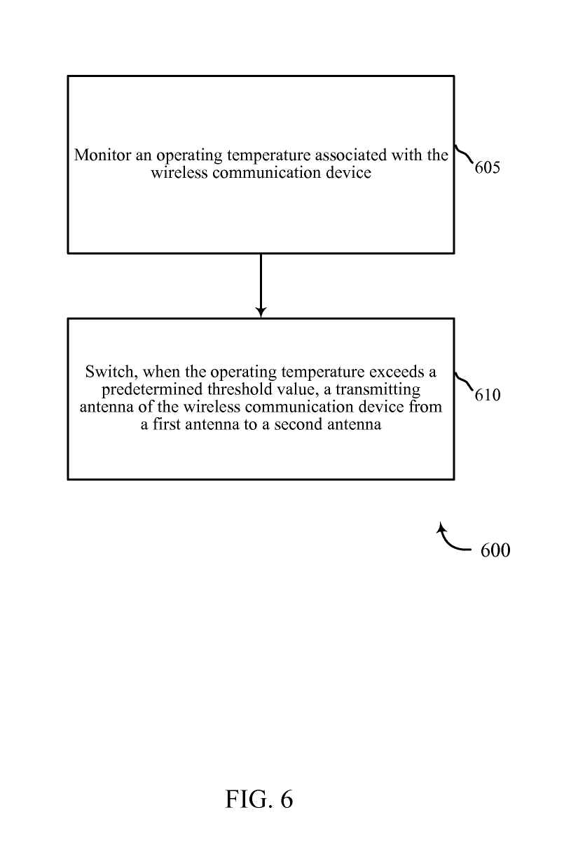

FIG. 6 is a flow chart illustrating an example of a method 600 for facilitating thermal management of a wireless communications device. The method 600 may, for example, be performed by devices such as the mobile devices 115 of FIGS. 1-5. In one implementation, a processor (e.g., the controller 210 of FIGS. 2-4) may execute one or more sets of codes to control the functional elements of the wireless device to perform the functions described below.

At block 605, an operating temperature associated with a wireless device is monitored. For example, the operating temperature may be monitored to determine if an excessive heat condition has occurred. The monitoring of the operating temperature may be provided by one or more sensors associated with the mobile devices 115 of FIGS. 1-4.

At block 610, a transmitting antenna is switched, when the operating temperature exceeds a predetermined threshold value, from a first antenna to a second antenna. A controller 210 of a mobile device 115 may, based on occurrence of the operating temperature exceeding the threshold value, communicate with the switches 215 to direct the switch 215 to switch the transmission signal from the first antenna to the second antenna to reduce the operating temperature of the mobile device 115.

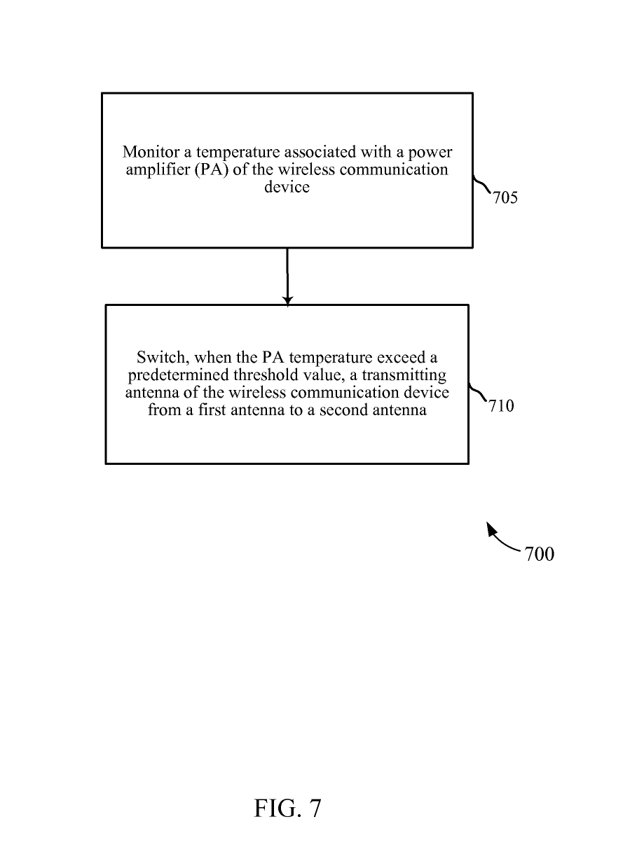

FIG. 7 is a flow chart illustrating an example of a method 700 for facilitating thermal management of a wireless communications device. The method 700 may, be performed by devices such as the mobile devices 115 of FIGS. 1-4. In one implementation, a processor (e.g., the controllers 210 of FIGS. 2-4) may execute one or more sets of codes to control the functional elements of the wireless device to perform the functions described below.

At block 705, a temperature associated with a PA of the wireless device is monitored. For example, the PA temperature of a mobile device 115 may be monitored by the sensors 205 to determine if an excessive heat condition has occurred.

At block 710, a transmitting antenna is switched, when the PA temperature exceeds a predetermined threshold value, from a first antenna to a second antenna. The controller 210 of the mobile device 115 may, based on occurrence of the PA temperature exceeding the threshold value, communicate with the switches 215 to direct the switch 215 to switch the transmission signal from the first antenna to the second antenna to reduce the operating temperature of the mobile device 115.

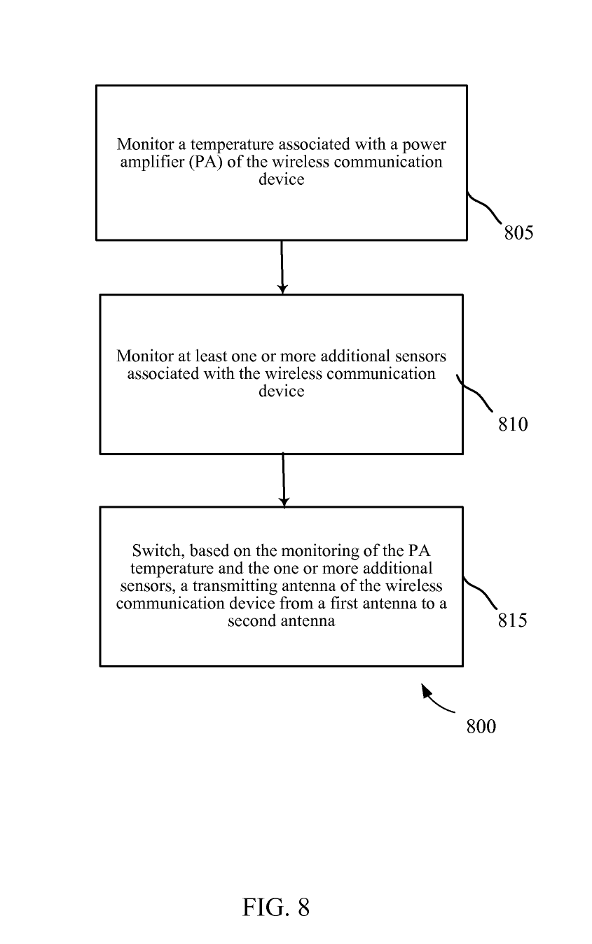

FIG. 8 is a flow chart illustrating an example of a method 800 for facilitating thermal management of a wireless communications device. The method 800 may, for example, be performed by devices such as the mobile devices 115 of FIGS. 1-4. In one implementation, a processor (e.g., the controllers 210 of FIGS. 2-4) may execute one or more sets of codes to control the functional elements of the wireless device to perform the functions described below.

At block 805, a temperature associated with a PA of the wireless device is monitored. For example, the PA temperature of a mobile device 115 may be monitored by the sensors 205, to determine if an excessive heat condition has occurred.

At block 810, at least one or more additional sensors are monitored. The one or more additional sensors (e.g., any of the sensors 435 of FIG. 4) may be in communication with, and provide information to a controller 210, the information being at least partially indicative of a temperature, physical condition, or status/state being monitored, etc.

At block 815, a transmitting antenna is switched, based on the PA temperature and the one or more additional sensors, from a first antenna to a second antenna. The controller 210 of the mobile device 115 may, based at least in part on the PA temperature and information from the one or more additional sensors 435, communicate with the switches 215 to direct the switch 215 to switch the transmission signal from the first antenna to the second antenna to reduce the operating temperature of the mobile device 115. As discussed above, the controllers 210 may implement a variety of algorithms to determine if the transmission antenna should be switched to the second antenna. As would be understood, the particular algorithm being implemented may depend on the number and/or particular type of sensors associated with the mobile device 115.

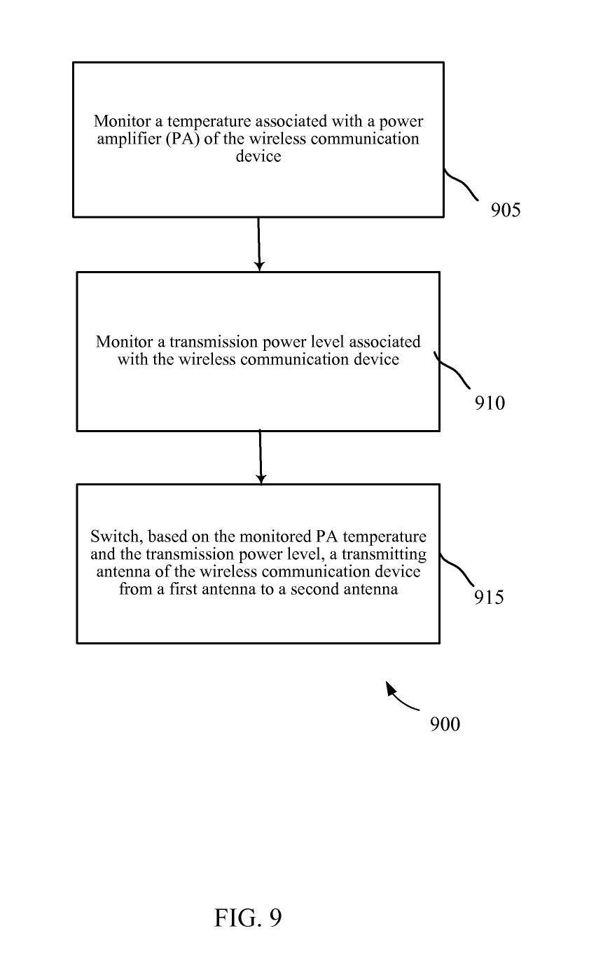

FIG. 9 is a flow chart illustrating an example method 900 for facilitating thermal management of a wireless communications device. The method 900 may, for example, be performed by devices such as the mobile devices 115 of FIGS. 1-4. In one implementation, a processor (e.g., the controllers 210 of FIGS. 2-4) may execute one or more sets of codes to control the functional elements of the wireless device to perform the functions described below.

At block 905, a temperature associated with a PA associated with the wireless device is monitored. For example, the PA temperature may be monitored by a sensor, to determine, at least in part, whether an excessive heat condition has occurred. The monitoring of the PA temperature may be provided by one or more sensors associated with the mobile devices 115 to 115-d being in operative communication with the controllers 210.

At block 910, a transmission power level associated with the wireless device is monitored. A controller 210 may be in communication with, for example, the CPU module 420 and/or any of the PAs 305 to transfer information indicative of the transmission power level at which the PA is transmitting. As discussed above with reference to FIGS. 5A and 5B, certain mobile devices 115 may include more than one PA 305. In such cases, a controller may monitor the transmission power level associated with each PA.

At block 915, a transmitting antenna is switched, based on the PA temperature and the transmission power level, from a first antenna to a second antenna. The controller 210 of the mobile device 115 may, based at least in part on the PA temperature and transmission power level, communicate with the switch 215 to direct the switch 215 to switch the transmission signal from the first antenna to the second antenna to reduce the operating temperature of the mobile device 115. As discussed above, the controllers 210 may implement a variety of algorithms to determine if the transmission antenna needs to be switched to the second antenna. As would be understood, the particular algorithm being implemented may depend on the number and/or particular type of sensors associated with the device. Further aspects may provide for reducing the transmission power level of the mobile device 115 in response to the excessive temperature situation.

The detailed description set forth above in connection with the appended drawings describes various examples and does not represent the only examples that may be implemented or that are within the scope of the claims. The term “exemplary” used throughout this description means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof

The various illustrative blocks and modules described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The functions described herein may be implemented in hardware, software executed by a processor, firmware, or any combination thereof If implemented in software executed by a processor, the functions may be stored on or transmitted over as one or more instructions or code on a computer-readable medium. Other examples and implementations are within the scope and spirit of the disclosure and appended claims. For example, due to the nature of software, functions described above can be implemented using software executed by a processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C).

Computer-readable media includes both computer storage media and communication media including any medium that facilitates transfer of a computer program from one place to another. A storage medium may be any available medium that can be accessed by a general purpose or special purpose computer. By way of example, and not limitation, computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include compact disc (CD), laser disc, optical disc, digital versatile disc (DVD), floppy disk and Blu-Ray disc where disks usually reproduce data magnetically, while discs reproduce data optically with lasers. Combinations of the above are also included within the scope of computer-readable media.

The previous description of the disclosure is provided to enable a person skilled in the art to make or use the disclosure. Various modifications to the disclosure will be readily apparent to those skilled in the art, and the generic principles defined herein may be applied to other variations without departing from the spirit or scope of the disclosure. Throughout this disclosure the term “example” or “exemplary” indicates an example or instance and does not imply or require any preference for the noted example. Thus, the disclosure is not to be limited to the examples and designs described herein but is to be accorded the widest scope consistent with the principles and novel features disclosed herein.

Techniques described herein may be used for various wireless communications systems such as CDMA, TDMA, FDMA, OFDMA, SC-FDMA, and other systems. The terms “system” and “network” are often used interchangeably. A CDMA system may implement a radio technology such as CDMA2000, Universal Terrestrial Radio Access (UTRA), etc. CDMA2000 covers IS-2000, IS-95, and IS-856 standards. IS-2000 Releases 0 and A are commonly referred to as CDMA2000 1x, 1x, etc. IS-856 (TIA-856) is commonly referred to as CDMA2000 1xEV-DO, High Rate Packet Data (HRPD), etc. UTRA includes Wideband CDMA (WCDMA) and other variants of CDMA. A TDMA system may implement a radio technology such as Global System for Mobile Communications (GSM). An OFDMA system may implement a radio technology such as Ultra Mobile Broadband (UMB), Evolved UTRA (E-UTRA), IEEE 802.11 (Wi-Fi), IEEE 802.16 (WiMAX), IEEE 802.20, Flash-OFDM□, etc. UTRA and E-UTRA are part of Universal Mobile Telecommunication System (UMTS). 3GPP Long Term Evolution (LTE) and LTE-Advanced (LTE-A) are new releases of UMTS that use E-UTRA. UTRA, E-UTRA, UMTS, LTE, LTE-A, and GSM are described in documents from an organization named “3rd Generation Partnership Project” (3GPP). CDMA2000 and UMB are described in documents from an organization named “3rd Generation Partnership Project 2” (3GPP2). The techniques described herein may be used for the systems and radio technologies mentioned above as well as other systems and radio technologies. The description below, however, describes an LTE system for purposes of example, and LTE terminology is used in much of the description below, although the techniques are applicable beyond LTE applications.

Thus, the following description provides examples, and is not limiting of the scope, applicability, or configuration set forth in the claims. Changes may be made in the function and arrangement of elements discussed without departing from the spirit and scope of the disclosure. Various examples may omit, substitute, or add various procedures or components as appropriate. For instance, the methods described may be performed in an order different from that described, and various steps may be added, omitted, or combined. Also, features described with respect to certain examples may be combined in other examples.

1. A method for thermal management of a wireless communication device having two or more antennas, the method comprising:
monitoring an operating temperature associated with the wireless communication device; and
switching, when the operating temperature exceeds a predetermined threshold value, a transmitting antenna of the wireless communications device from a first antenna to a second antenna.

2. The method of claim 1, wherein the monitoring comprises:
monitoring a temperature associated with a power amplifier (PA) of the wireless communication device.

3. The method of claim 1, wherein the monitoring comprises:
monitoring a temperature identified by a sensor coupled with a power amplifier (PA) of the wireless communication device.

4. The method of claim 1, wherein the monitoring comprises:
monitoring a temperature associated with a power amplifier (PA) of the wireless communication device and at least one of one or more additional sensors associated with the wireless communication device.

5. The method of claim 1, further comprising:
monitoring a transmission power level associated with the wireless communication device, wherein the switching the transmitting antenna is based at least in part on the monitored transmission power level.

6. The method of claim 1, further comprising:
reducing a transmission power level of the wireless communication device to a predetermined transmission power level when the operating temperature of the wireless communication device exceeds the predetermined threshold value.

7. The method of claim 1, further comprising:
switching the transmitting antenna from the second antenna to the first antenna when the monitored operating temperature of the wireless communication device falls below a second predetermined threshold value.

8. The method of claim 1, further comprising:
switching the transmitting antenna from the second antenna to the first antenna after a predetermined time period has elapsed and the monitored operating temperature of the wireless communications device does not fall or increase in excess of a threshold amount from the predetermined threshold value.

9. The method of claim 1, wherein the switching the transmitting antenna from the first antenna to the second antenna is initiated when the operating temperature exceeds the predetermined threshold value for predetermined period of time.

10. The method of claim 1, wherein the wireless communication device comprises user equipment communicatively coupled with, and operating on, a multicarrier communications system.

11. The method of claim 1, further comprising:
determining the second antenna, from a plurality of antennas associated with the wireless communication device, based at least in part on the operating temperature.

12. A wireless communication device configured for thermal management, comprising:
means for monitoring an operating temperature associated with the wireless communication device; and
means for switching, when the operating temperature exceeds a predetermined threshold value, a transmitting antenna of the wireless communication device from a first antenna to a second antenna.

13. The wireless communication device of claim 12, wherein the monitoring further comprises:
means for monitoring a temperature associated with a power amplifier (PA) of the wireless communication device.

14. The wireless communication device of claim 12, wherein the monitoring further comprises:
means for monitoring a temperature identified by a sensor coupled with a power amplifier (PA) of the wireless communication device.

15. The wireless communications device of claim 12, wherein the monitoring further comprises:
means for monitoring a temperature associated with a power amplifier (PA) of the wireless communication device and at least one of one or more additional sensors associated with the wireless communication device.

16. The wireless communications device of claim 12, further comprising:
means for monitoring a transmission power level associated with the wireless communication device, wherein the switching the transmitting antenna is based at least in part on the monitored transmission power level.

17. The wireless communications device of claim 12, further comprising:
means for reducing a transmission power level of the wireless communication device to a predetermined transmission power level when the operating temperature of the wireless communication device exceeds the predetermined threshold value.

18. The wireless communications device of claim 12, further comprising:
means for switching the transmitting antenna from the second antenna to the first antenna when the monitored operating temperature of the wireless communication device falls below a second predetermined threshold value.

19. The wireless communications device of claim 12, further comprising:
means for switching the transmitting antenna from the second antenna to the first antenna after a predetermined time period has elapsed and the monitored operating temperature of the wireless communication device does not fall or increase in excess of a threshold amount from the predetermined threshold value.

20. The wireless communications device of claim 12, wherein the means for switching the transmitting antenna from the first antenna to the second antenna is initiated when the operating temperature exceeds the predetermined threshold value for predetermined period of time.

21. The wireless communications device of claim 12, wherein the wireless communication device comprises user equipment communicatively coupled with, and operating on, a multicarrier communication system.

22. The wireless communications device of claim 12, further comprising:
means for determining the second antenna, from a plurality of antennas associated with the wireless communication device, based at least in part on the operating temperature.

23. A computer program product for thermal management of a wireless communication device, comprising:
a non-transitory computer readable medium comprising:
code for monitoring an operating temperature associated with the wireless communication device; and
code for switching, when the operating temperature exceeds a predetermined threshold value, a transmitting antenna of the wireless communication device from a first antenna to a second antenna.

24. The computer program product of claim 23, wherein the code for monitoring further comprises:
code for monitoring a temperature associated with a power amplifier (PA) of the wireless communication device.

25. The computer program product of claim 23, wherein the code for monitoring further comprises:
code for monitoring a temperature identified by a sensor coupled with a power amplifier (PA) of the wireless communication device.

26. The computer program product of claim 23, wherein the code for monitoring further comprises:
code for monitoring a temperature associated with a power amplifier (PA) of the wireless communication device and at least one of one or more additional sensors associated with the wireless communication device.

27. The computer program product of claim 23, further comprising:
code for monitoring a transmission power level associated with the wireless communication device, wherein the switching the transmitting antenna is based at least in part on the monitored transmission power level.

28. The computer program product of claim 23, further comprising:
code for reducing a transmission power level of the wireless communication device to a predetermined transmission power level when the operating temperature of the wireless communications device exceeds the predetermined threshold value.

29. The computer program product of claim 23, further comprising:
code for switching the transmitting antenna from the second antenna to the first antenna when the monitored operating temperature of the wireless communication device falls below a second predetermined threshold value.

30. The computer program product of claim 23, further comprising:
code for switching the transmitting antenna from the second antenna to the first antenna after a predetermined time period has elapsed and the monitored operating temperature of the wireless communication device does not fall or increase in excess of a threshold amount from the predetermined threshold value.

31. The computer program product of claim 23, wherein the switching the transmitting antenna from the first antenna to the second antenna is initiated when the operating temperature exceeds the predetermined threshold value for predetermined period of time.

32. The computer program product of claim 23, wherein the wireless communication device comprises user equipment communicatively coupled with, and operating on, a multicarrier communications system.

33. The computer program product of claim 23, further comprising:
code for determining the second antenna, from a plurality of antennas associated with the wireless communication device, based at least in part on the operating temperature.

34. A wireless communication device configured for thermal management, the wireless communication device comprising:
at least one controller configured to:
monitor an operating temperature associated with the wireless communication device; and
switch, when the operating temperature exceeds a predetermined threshold value, a transmitting antenna of the wireless communication device from a first antenna to a second antenna; and
a memory coupled to the at least one controller.

35. The wireless communication device of claim 34, wherein the controller is further configured to:
monitor a temperature associated with a power amplifier (PA) of the wireless communication device.

36. The wireless communication device of claim 34, wherein the controller is further configured to:
monitor a temperature identified by a sensor coupled with a power amplifier (PA) of the wireless communication device.

37. The wireless communication device of claim 34, wherein the controller is further configured to:
monitor a temperature associated with a power amplifier (PA) of the wireless communication device and at least one of one or more additional sensors associated with the wireless communication device.

38. The wireless communication device of claim 34, wherein the controller is further configured to:
monitor a transmission power level associated with the wireless communication device, wherein the switching the transmitting antenna is based at least in part on the monitored transmission power level.

39. The wireless communication device of claim 34, wherein the controller is further configured to:
reduce a transmission power level of the wireless communication device to a predetermined transmission power level when the operating temperature of the wireless communication device exceeds the predetermined threshold value.

40. The wireless communication device of claim 34, wherein the controller is further configured to:
switch the transmitting antenna from the second antenna to the first antenna when the monitored operating temperature of the wireless communication device falls below a second predetermined threshold value.

41. The wireless communication device of claim 34, wherein the controller is further configured to:
switch the transmitting antenna from the second antenna to the first antenna after a predetermined time period has elapsed and the monitored operating temperature of the wireless communications device does not fall or increase in excess of a threshold amount from the predetermined threshold value.

42. The wireless communication device of claim 34, wherein the switching the transmitting antenna from the first antenna to the second antenna is initiated when the operating temperature exceeds the predetermined threshold value for a predetermined period of time.

43. The wireless communication device of claim 34, wherein the wireless communication device comprises user equipment communicatively coupled with, and operating on, a multicarrier communications system.

44. The wireless communication device of claim 34, wherein the controller is further configured to:
determine the second antenna, from a plurality of antennas associated with the wireless communication device, based at least in part on the operating temperature.
